(19) United States
(12) Patent Application Publication
(10) Pub. No.: US 2021/0104659 A1
(43) Pub. Date: Apr. 8, 2021

(54) MEMORY CELL, MEMORY DEVICE, AND METHODS OF FORMING THE SAME

(71) Applicant: Agency for Science, Technology and Research, Singapore (SG)

(72) Inventors: Hideaki Fukuzawa, Singapore (SG); Jun Yu, Sinagpore (SG); Michael Han, Singapore (SG); Xinpeng Wang, Singapore (SG); Vladimir Bliznetsov, Singapore (SG)

(21) Appl. No.: 16/072,965

(22) PCT Filed: Jan. 19, 2017
(86) PCT No.: PCT/SG2017/050028

§ 371 Date: Jul. 26, 2018

(30) Foreign Application Priority Data
Jan. 29, 2016 (SG) 10201600735X

(51) Int. Cl. H01L 43/02; H01L 27/22; H01L 43/10; H01L 43/12

(52) U.S. Cl. CPC H01L 43/02; H01L 43/12; H01L 43/10; H01L 27/222

(57) ABSTRACT

Various embodiments may provide a memory cell including a magnetic pinned layer with a substantially fixed magnetization direction, a crystalline spacer layer in contact with the magnetic pinned layer, and a magnetic storage layer. The magnetic storage layer may include an amorphous interface sub-layer in contact with the crystalline spacer layer, the amorphous interface sub-layer including a first alloy of iron (Fe) and at least one element. The amorphous storage layer may also include an amorphous enhancement sub-layer in contact with the amorphous interface sub-layer, the amorphous enhancement sub-layer including a second alloy of iron (Fe) and at least one element. The memory cell may additionally include a cap layer in contact with the amorphous enhancement sub-layer. A concentration of the at least one further element comprised in the first alloy and a concentration of the at least one further element comprised in the second alloy may be different.

### CROSS-REFERENCE TO RELATED APPLICATION

This application claims the benefit of priority of Singapore application No. 10201600735X filed on Jan. 29, 2016, the contents of it being hereby incorporated by reference in its entirety for all purposes.

### TECHNICAL FIELD

Various aspects of this disclosure relate to memory cells and/or memory devices. Various aspects of this disclosure relate to methods of forming memory cells and/or memory devices.

### BACKGROUND

FIG. 1 shows a conventional spin-transfer magnetic random access memory (STT-MRAM) 100 with a perpendicular magnetic tunnel junction (p-MTJ). This is the most common MRAM structure. The critical current density J_{c0} achieved for this structure is about 2.0-4.0 MA/cm², and this structure has been considered as a non-volatile memory (NVM) to replace embedded flash memory. Although the STT-MRAM may be able to replace embedded flash memory, the switching speed is relatively slow (10-100 nanoseconds or nsec), and is much slower than the initial expectation for fast switching STT-MRAM (<10 nsec). Such a slow speed may not be sufficient for the realization of STT-MRAM in embedded cache applications (which require at least <10 nsec, preferably <5 nsec). The main reason for such a slow switching speed in STT-MRAM is that the required current for switching is very large. The realization of faster switching is limited by the long term reliability of the devices. In order to realize embedded cache memory using STT-MRAM, the reduction of switching current is critically important. However, this is very difficult issue to solve it. Although many studies have been done to solve this issue, none of these studies has been able to solve the issue yet.

The switching speed is related to the Gilbert damping factor α of a storage layer (alternatively referred to as a free layer). The Gilbert damping factor α directly determines the dynamics of the magnetization switching of the storage layer, as shown in the following Landau-Lifshitz-Gilbert equation (LLG) equation:

$$\frac{\partial M}{\partial t} = - γ ( M \times {H}_{eff} ) + \frac{α}{\vert M \vert} ( M \times \frac{\partial M}{\partial t} ) \qquad ( 1 )$$

where M is the magnetization, t is time, γ is the electron gyromagnetic ratio, H_{eff} is the effective magnetic field, and α is the Gilbert damping factor. FIG. 2 is a schematic illustrating the dynamics of the Landau-Lifshitz-Gilbert equation (LLG) equation.

The critical current density J_{c0} is proportional to the Gilbert damping factor, a, as showing in the following equation:

$${J}_{c 0} = \frac{4 e}{ℏ} \frac{α}{g ( θ )} {K}_{u} V \qquad ( 2 )$$

where Kᵤ is the uniaxial perpendicular anisotropy energy, V is the volume, h is the Planck constant, and g(θ) is the Slonczewski's expression (θ is the angle between the magnetization directions of the storage layer and the fixed layer).

### SUMMARY

Various embodiments may provide a memory cell. The memory cell may include a magnetic pinned layer with a substantially fixed magnetization direction. The memory cell further includes a crystalline spacer layer in contact with the magnetic pinned layer. The memory cell also includes a magnetic storage layer. The magnetic storage layer may include an amorphous interface sub-layer in contact with the crystalline spacer layer, the amorphous interface sub-layer including a first alloy of iron (Fe) and at least one element selected from a group consisting of boron (B), silicon (Si), aluminum (Al), and magnesium (Mg). The magnetic storage layer may also include an amorphous enhancement sub-layer in contact with the amorphous interface sub-layer, the amorphous enhancement sub-layer including a second alloy of iron (Fe) and at least one non-ferromagnetic element selected from a group consisting of boron (B), silicon (Si), aluminum (Al), and magnesium (Mg). The memory cell may additionally include a cap layer in contact with the amorphous enhancement sub-layer. A concentration of the at least one further element comprised in the first alloy and a concentration of the at least one further element comprised in the second alloy are different.

Various embodiments may provide a method of forming a memory cell. The method may include forming a magnetic pinned layer with a substantially fixed magnetization direction. The method may also include forming a crystalline spacer layer in contact with the magnetic pinned layer. The method may additionally include forming a magnetic storage layer. The magnetic storage layer may include an amorphous interface sub-layer in contact with the crystalline spacer layer, the amorphous interface sub-layer including a first alloy of iron (Fe) and at least one element selected from a group consisting of boron (B), silicon (Si), aluminum (Al), and magnesium (Mg). The magnetic storage layer may also include an amorphous enhancement sub-layer in contact with the amorphous interface sub-layer, the amorphous enhancement layer including a second alloy of iron (Fe) and at least one element selected from a group consisting of boron (B), silicon (Si), aluminum (Al), and magnesium (Mg). The method may also include forming a cap layer in contact with the amorphous enhancement sub-layer. A concentration of the at least one further element comprised in the first alloy and a concentration of the at least one further element comprised in the second alloy are different.

In various embodiments, a memory device may be provided. The memory device may include a memory cell including a magnetic pinned layer with a substantially fixed magnetization direction. The memory cell may also include a crystalline spacer layer in contact with the magnetic pinned layer. The memory cell may further include an magnetic storage layer including an amorphous interface sub-layer in contact with the crystalline spacer layer, the amorphous interface sub-layer including a first alloy of iron (Fe) and at least one element selected from a group consisting of boron (B), silicon (Si), aluminum (Al), and magnesium (Mg). The magnetic storage layer may additionally include an amorphous enhancement sub-layer in contact with the amorphous interface sub-layer, the amorphous enhancement layer including a second alloy of iron (Fe) and at least one element selected from a group consisting of boron (B), silicon (Si), aluminum (Al), and magnesium (Mg). The memory cell may also include a cap layer in contact with the amorphous enhancement sub-layer. The memory device may further include one or more electrodes coupled to the memory cell. A concentration of the at least one further element comprised in the first alloy and a concentration of the at least one further element comprised in the second alloy are different.

In various embodiments, a method of forming a memory device may be provided. The method may include forming a memory cell including forming a magnetic pinned layer with a substantially fixed magnetization direction. The method may also include forming a crystalline spacer layer in contact with the magnetic pinned layer. The method may further include forming a magnetic storage layer. The magnetic storage layer may include an amorphous interface sub-layer in contact with the crystalline spacer layer, the amorphous interface sub-layer including a first alloy of iron (Fe) and at least one element selected from a group consisting of boron (B), silicon (Si), aluminum (Al), and magnesium (Mg). The magnetic storage layer may also include an amorphous enhancement sub-layer in contact with the amorphous interface sub-layer, the amorphous enhancement layer including a second alloy of iron (Fe) and at least one element selected from a group consisting of boron (B), silicon (Si), aluminum (Al), and magnesium (Mg). The method may also include forming a cap layer in contact the amorphous enhancement sub-layer. The method may additionally include forming one or more electrodes coupled to the memory cell. A concentration of the at least one further element comprised in the first alloy and a concentration of the at least one further element comprised in the second alloy are different.

Various embodiments may provide a memory cell. The memory cell may include a magnetic pinned layer with a substantially fixed magnetization direction. The memory cell may also include a crystalline spacer layer in contact with the magnetic pinned layer. The memory cell may further include a magnetic storage layer in contact with the crystalline spacer layer. The memory cell may also include a cap layer in contact with the magnetic storage layer including at least one element selected from a group consisting of molybdenum (Mo) and tungsten (W). The magnetic storage layer may be amorphous.

Various embodiments may provide a method of forming a memory cell. The method may include forming a magnetic pinned layer with a substantially fixed magnetization direction. The method may also include forming a crystalline spacer layer in contact with the magnetic pinned layer. The method may additionally include forming a magnetic storage layer in contact with the crystalline spacer layer. The method may also include forming a cap layer in contact with the magnetic storage layer including at least one element selected from a group consisting of molybdenum (Mo) and tungsten (W). The magnetic storage layer may be amorphous.

Various embodiments may provide a memory device. The memory device may include a magnetic pinned layer with a substantially fixed magnetization direction. The memory cell may also include a crystalline spacer layer in contact with the magnetic pinned layer. The memory cell may further include a magnetic storage layer in contact with the crystalline spacer layer. The memory cell may also include a cap layer in contact with the magnetic storage layer including at least one element selected from a group consisting of molybdenum (Mo) and tungsten (W). The magnetic storage layer may be amorphous. The memory device may further include one or more electrodes coupled to the memory cell.

Various embodiments may provide a method of forming a memory device. The method may include forming a memory cell including forming a magnetic pinned layer with a substantially fixed magnetization direction. The method may also include forming a crystalline spacer layer in contact with the magnetic pinned layer. The method may further include forming a magnetic storage layer in contact with the crystalline spacer layer. The method may also include forming a cap layer in contact with the magnetic storage layer including at least one element selected from a group consisting of molybdenum (Mo) and tungsten (W). The magnetic storage layer may be amorphous. The method may also include forming one or more electrodes coupled to the memory cell.

### BRIEF DESCRIPTION OF THE DRAWINGS

The invention will be better understood with reference to the detailed description when considered in conjunction with the non-limiting examples and the accompanying drawings, in which:

FIG. 1 shows a conventional spin-transfer magnetic random access memory (STT-MRAM) with a perpendicular magnetic tunnel junction (p-MTJ).

FIG. 2 is a schematic illustrating the dynamics of the Landau-Lifshitz-Gilbert equation (LLG) equation.

FIG. 3 shows a memory cell according to various embodiments.

FIG. 4 is a schematic showing a method of forming a memory cell according to various embodiments.

FIG. 5A shows a memory cell according to various embodiments.

FIG. 5B shows a schematic image for high-resolution transmission electron microscopy (TEM) being conducted at an interface between the amorphous interface layer and the amorphous enhancement layer of a part of the memory cell according to various embodiments shown in FIG. 5A. The amorphous structure of the storage layer may be detected by Fast Fourier Transform (FFT) analysis of a real image of TEM. Spot diffraction occurs for a crystalline structure, while ring-shape diffraction occurs for an amorphous structure.

FIG. 6A is a plot of simulation data for critical switching current density J_{c0} (mega-amperes per square centimeter or MA/cm²) comparing the storage layer according to various embodiments with conventional storage layers.

FIG. 6B is a plot of simulation data for critical switching current density J_{c0} as a function of switching time (nanoseconds or nsec) showing the decreased critical current density J_{c0} exhibited by the storage layer according to various embodiments.

FIG. 7A is a plot of the number of conventional memory cell devices as a function of voltage (in volts or V) showing the spread of devices at different resistance values when the devices are at the “0” state and at the “1” state.

FIG. 7B is a plot of the number of memory cell devices according to various embodiments as a function of voltage (in volts or V) showing the spread of devices at different resistance ratios values when the devices are at the “0” state and at the “1” state.

FIG. 8 shows memory devices according to various embodiments.

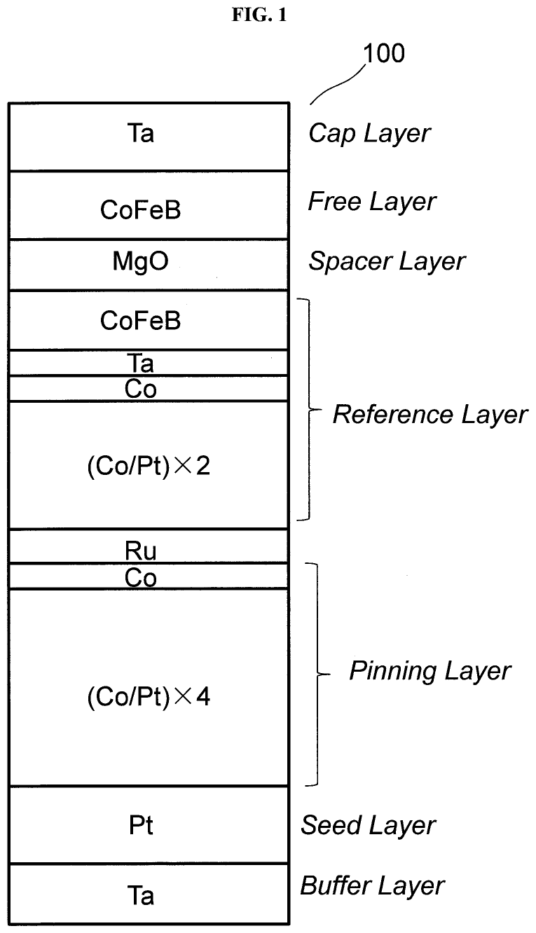

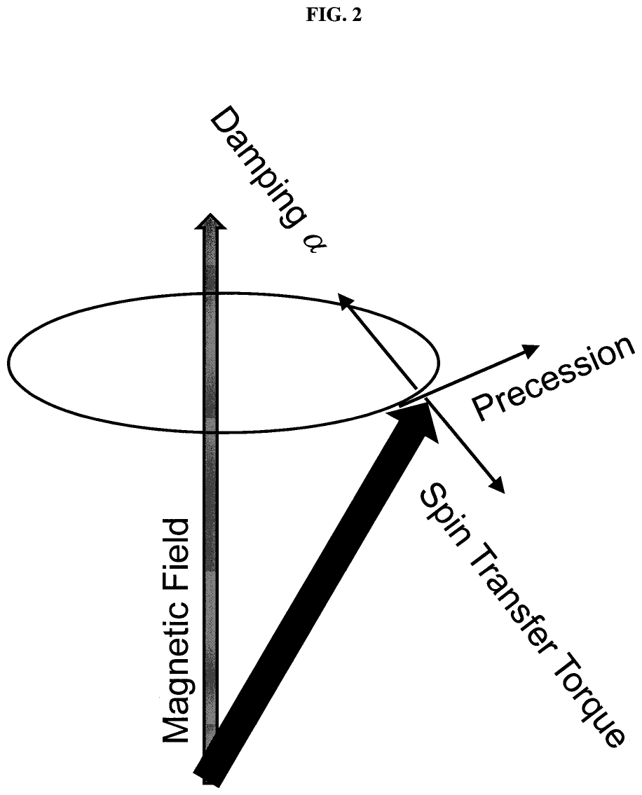

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

Embodiments described in the context of one of the methods or memory cells/devices are analogously valid for the other methods or memory cells/devices. Similarly, embodiments described in the context of a method are analogously valid for a memory cell/device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may also be used herein to mean that the deposited material may be formed “indirectly on” the implied side or surface with one or more additional layers being arranged between the implied side or surface and the deposited material. In other words, a first layer “over” a second layer may refer to the first layer directly on the second layer, or that the first layer and the second layer are separated by one or more intervening layers.

The device arrangement as described herein may be operable in various orientations, and thus it should be understood that the terms “top”, “bottom”, etc., when used in the following description are used for convenience and to aid understanding of relative positions or directions, and not intended to limit the orientation of the device arrangement.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

In order to reduce the critical switching current J_{c0} to improve device performance, the Gilbert damping factor, α, would need to be reduced, as can be expected from Equation (2). The Gilbert damping factor, α, is related to the material of the storage later. A nominal value of α for a cobalt-iron-boron (CoFeB) layer is about 0.125, although it should be noted that the value of α may be inconsistent amongst various reports. Since the absolute values of a are different dependent on the measuring method, the relative comparison using the same measuring method may be more meaningful.

There have been many studies of the damping factor α for different materials. Some papers have reported a very small α of less than 0.005 by using Heusler alloy. However, this small α has been obtained only by modeling a film structure without a spacer layer, and the results are therefore not applicable to MRAM cells. The J_{c0} based on a MRAM cell with a spacer layer, may become even larger than the CoFeB layer. Therefore, the realization of small α by the model film structure may not be useful for practical applications.

It has also been reported that a may be reduced by using rapid thermal annealing (RTA) for a very short duration of time, even on a CoFeB layer. The diffusion of each element in the storage layer seems to be changed by the adoption of RTA, and appears to allow the CoFeB layer to remain in an amorphous state. This is an important insight that the use of amorphous state results in the decrease of Gilbert damping factor α, and it can be used to estimate J_{c0} using simulation. However, the report relates to a model experiment which is not applicable to production process, and the actual back-end-of-line (BEOL) process needs much longer time anneal than RTA at 400 degree Celsius. The duration time of RTA is typically less than 1 minute, but the BEOL thermal process would require a time longer than 1 minute, typically about 30 minutes. By using such a thermal BEOL process, the CoFeB storage layer would result in crystallization either fully or partially, resulting in the increase of Gilbert damping factor, α. A BEOL process as referred herein is any required processes after perpendicular magnetic tunnel junction (p-MTJ) deposition in which complementary metal oxide semiconductor (CMOS) transistors are formed on the same substrate. The substrate may be a silicon substrate.

The use of an amorphous layer in the storage layer in in-plane STT-MRAM has been studied before. By using an amorphous layer as part of a storage layer, such as a crystalline magnetic layer/NiFe-X amorphous layer structure (U.S. Pat. No. 8,736,004) or a crystalline magnetic layer/CoFeB-amorphous layer/crystalline magnetic layer structure (U.S. Pat. No. 8,080,432), J_{c o} may be decreased. However, the amorphous layer forms only part of the storage layer. It has been commonly known that the magnetic layer contacting the magnesium oxide (MgO) spacer should be crystalline CoFeB so as to obtain a large magnetoresistance (MR) ratio both for pinned layer and the storage layer. In fact, there are studies of obtaining higher quality and thinner crystalline CoFeB layers as interface to the spacer layer (Pellgren et al, IEEE-Intermag 2015, GP-10). It has been previously thought that it is necessary to have a crystalline magnetic layer contacting the MgO spacer layer. Accordingly, only a part of the storage layer in U.S. Pat. No. 8,736,004 is amorphous. Also, since MgO layer is crystalline layer, the interface magnetic layer which is typically a conventional CoFeB layer, also tends to be crystalline.

Various embodiments may use a full amorphous storage layer to reduce switching current. This approach is completely different from the existing approaches. As described in the above, the use of crystalline interface magnetic materials to contact the MgO layer is seen as “common sense” and considered to be justifiable until now. In addition to the opposite way of thinking from the existing approaches, various embodiments may include specific materials to realize the amorphous storage layer even after the high temperature BEOL process. The magnetic storage layer may include various amorphous stable materials.

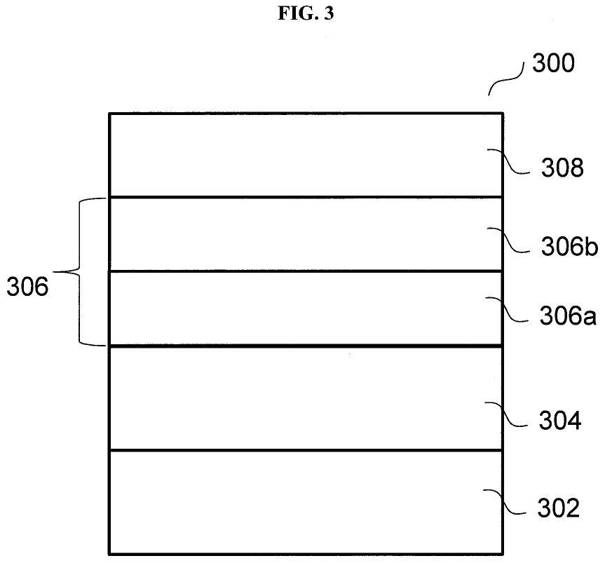

FIG. 3 shows a memory cell 300 according to various embodiments. The memory cell 300 includes a magnetic pinned layer 302 with a substantially fixed magnetization direction. The memory cell 300 further includes a crystalline spacer layer 304 in contact with or on the magnetic pinned layer 302. The memory cell 300 also includes a magnetic storage layer 306. The magnetic storage layer 306 includes an amorphous interface sub-layer 306a in contact with or on the crystalline spacer layer 304, the amorphous interface sub-layer 306a including a first alloy of iron (Fe) and at least one element selected from a group consisting of boron (B), silicon (Si), aluminum (Al), and magnesium (Mg). The magnetic storage layer 306 may also include an amorphous enhancement sub-layer 306b in contact with or on the amorphous interface sub-layer 306a, the amorphous enhancement sub-layer 306b including a second alloy of iron (Fe) and at least one element selected from a group consisting of boron (B), silicon (Si), aluminum (Al), and magnesium (Mg). The memory cell 300 may additionally include a cap layer 308 inn contact with or on the amorphous enhancement sub-layer 306b. A concentration of the at least one further element comprised in the first alloy and a concentration of the at least one further element comprised in the second alloy are different.

In other words, the memory cell 300 includes a spacer layer 304 between a magnetic storage layer 306 and a magnetic pinned layer 302. The magnetic storage layer 306 may include an amorphous interface sub-layer 306a and an amorphous enhancement sub-layer 306b in contact with or on the amorphous interface sub-layer 306a. The memory cell 300 also includes a cap layer 308 in contact with or on the amorphous enhancement sub-layer 306b. Both the amorphous interface sub-layer 306a and the amorphous enhancement sub-layer 306b include an alloy of iron and at least one element chosen from boron, silicon, aluminum and magnesium. However, the at least one element in the alloy of amorphous enhancement sub-layer 306b may occupy a different percentage compared to the at least one element in the alloy of amorphous interface sub-layer 306b.

Various embodiments may provide a memory cell having an improved Gilbert damping factor, a. Various embodiments may go against “common sense” by having the amorphous interface sub-layer 306a and the amorphous enhancement sub-layer 306b instead of a crystalline storage layer.

The storage layer 306 may also be referred to as a free layer. During operation, the magnetization direction of the storage layer 306 may switch between a first direction and a second direction opposite the first direction. In contrast, the magnetization direction of the magnetic pinned layer 302 is fixed to the first direction. Accordingly, a first logic state may be defined in the memory cell 300 when the magnetization direction of the storage layer 306 is parallel to the magnetization direction of the pinned layer 302, and a second logic state may be defined in the memory cell 300 when the magnetization direction of the storage layer 306 is opposite or anti-parallel to the magnetization direction of the pinned layer 302.

In various embodiments, the storage layer 306 is entirely amorphous.

The interface sub-layer 306a and the enhancement sub-layer 306b may have amorphous or non-crystalline structure, i.e. the structure of the interface sub-layer 306a, and the structure of the enhancement sub-layer 306 may lack the long-range order characteristic of a crystal.

A layer may include a stack of multiple sub-layers. Accordingly, a “sub-layer” as used in the present context may be a convenient notation to refer to a layer of a plurality of layers which form the stack. For instance, the interface sub-layer 306a and the enhancement sub-layer 306b may be layers which together form the storage layer 306.

The amorphous interface sub-layer 306a may include FeₐB_{b}Si_{c}Al_{d}Mgₑ. The amorphous enhancement sub-layer 306b may include Fe_{A}B_{B}Si_{C}Al_{D}Mg_{E}.

The amorphous interface sub-layer 306a may include Fe and at least one element of B, Si, Al and Mg. The amorphous interface sub-layer 306a may or may not include all elements of B, Si, Al and Mg. The amorphous interface sub-layer 306a may include a magnetoresistive effect between the amorphous interface sub-layer 306a and the spacer layer 304.

The amorphous enhancement sub-layer 306b may include Fe and at least one element of B, Si, Al and Mg. The amorphous enhancement sub-layer 306b may or may not include all elements of B, Si, Al and Mg. The amorphous enhancement sub-layer 306b may be configured to maintain an amorphous structure for the amorphous storage layer 306 during thermal annealing.

In various embodiments, a concentration of the at least one element of the second alloy may be higher than a concentration of the at least one element of the first alloy.

The values of a, b, c, d, e and A, B, C, D, E may be in atomic percentage (%).

In various embodiments, the value of “a” may be any value between about 40 (%) to about 90 (%). The sum of b, c, d and e (i.e. b+c+d+e) may be any value between about 10 (%) to about 60 (%). The sum of a, b, c, d and e (i.e. a+b+c+d+e) may be 100 (%). For instance, the amorphous interface sub-layer may include Fe₉₀B₁₀, Fe₄₀B₂₀Si₂₀Al₂₀, or Fe₆₀B₁₀Si₁₀Al₁₀Mg₁₀.

In various embodiments, the value of A may be any value between about 40 (%) to about 90 (%). The sum of B, C, D and E (i.e. B+C+D+E) may be any value between about 10 (%) to about 60 (%). The sum of A, B, C, D and E (i.e. A+B+C+D+E) may be 100 (%).

In various embodiments, the at least one element comprised in the first alloy, i.e. B, Si, Al, and/or Mg may be a non-ferromagnetic element. Similarly, the at least one element comprised in the second alloy, i.e. B, Si, Al, and/or Mg may be a non-ferromagnetic element.

The percentage of iron in the second alloy may be lower than the percentage of iron in the first alloy. The first alloy and/or the second alloy may include a further ferromagnetic element in addition to Fe, such as cobalt (Co). The percentage of ferromagnetic elements in the second alloy may be lower than the percentage of ferromagnetic elements in the first alloy.

In various embodiments, the at least one element of the first alloy and the at least one element of the second alloy may be same. In various other embodiments, the first alloy and the second alloy may be different.

In various embodiments, the total concentration of the at least one element selected from a group consisting of boron (B), silicon (Si), aluminum (Al), and magnesium (Mg) for the amorphous enhancement layer, and the total concentration of the at least one element selected from a group consisting of boron (B), silicon (Si), aluminum (Al), and magnesium (Mg) for the amorphous interface layer may be different. The total concentration of the at least one element selected from a group consisting of boron (B), silicon (Si), aluminum (Al), and magnesium (Mg) for the amorphous enhancement layer may be greater than the total concentration of the at least one element selected from a group consisting of boron (B), silicon (Si), aluminum (Al), and magnesium (Mg) for the amorphous interface layer.

In various embodiments, a concentration of the at least one element of the second alloy may be higher than a concentration of the at least one element of the first alloy.

The sum of b, c, d and e (i.e. b+c+d+e) may be smaller than the sum of B, C, D and E (i.e. B+C+D+E), i.e. (b+c+d+e)<(B+C+D+E). For instance, when the amorphous interface sub-layer 306a includes Fe₇₀B₁₀Si₁₀Al₁₀, the amorphous enhancement sub-layer 306b may include Fe₄₀B₂₀Si₂₀Al₂₀ or Fe₄₀B₆₀.

In various embodiments, the amorphous interface sub-layer may include FeB, FeSi, or FeAl (i.e. FeₐB_{b}, Feₐ,Si_{c}, or FeₐAl_{d}).

In various embodiments, the amorphous enhancement sub-layer may include FeB, FeSi, or FeAl (i.e. Fe_{A}B_{B}, Fe_{A},Si_{C}, or Fe_{A}Al_{D}).

In various embodiments, the spacer layer 304 may be crystalline or may include a crystalline structure. The spacer layer 304 may include magnesium oxide (MgO).

The magnetic pinned layer 302 may be formed from or may include a material including cobalt (Co), Iron (Fe), and Boron (B).

The cap layer 308 may include at least one material selected from a group consisting of molybdenum (Mo), tungsten (W), and magnesium oxide (MgO). The cap layer 308 may be formed from a material including Mo, W, MgO or any combination thereof. The cap layer 308 may be configured to maintain an amorphous structure of the amorphous storage layer 306 during thermal annealing by controlling diffusion of the at least one element from the first alloy of the amorphous interface layer.

In various embodiments, the memory cell may be or may include a top type MTJ. The crystalline spacer layer 304 may be on the magnetic pinned layer 302. The amorphous interface sub-layer 306a may be on the crystalline spacer layer 304. The amorphous enhancement sub-layer 306b may be on the amorphous interface sub-layer 306a. The cap layer 308 may be on the amorphous enhancement sub-layer 306b. In various other embodiments, the memory cell may be or may include a bottom MTJ. In the present context, a first layer in contact with a second layer may refer to situations in which a first layer is on the second layer, or may refer to situations in which a second layer is on the first layer.

In various embodiments, the memory cell 300 may include a magnetic pinning layer. The memory cell 300 may also include a Ruderman-Kittel-Kasuya-Yosida (RKKY) coupling layer over or on the pinning layer. The magnetic pinned layer may be over the Ruderman-Kittel-Kasuya-Yosida (RKKY) coupling layer.

The memory cell 300 may also include a buffer layer. The memory cell 300 may further include a seed layer over or on the buffer layer. The magnetic pinning layer may be over or on the seed layer.

The memory cell 300 may also include a protection layer over the cap layer 308. The protection layer may be configured to protect the cap layer 308 from damage, e.g. during lithography process. The protection layer may be also referred to as an additional layer. The protection layer may be disposed on the cap layer 308 such that the cap layer 308 is between the additional layer and the amorphous storage layer 306.

The protection layer may include at least one material selected from a group consisting of tantalum (Ta), ruthenium (Ru), and copper (Cu).

In various embodiments, the magnetic pinned layer 302 and the amorphous storage layer 306 may have magnetizations perpendicular to a film plane of the magnetic pinned layer 302. The magnetic pinned layer and the amorphous storage layer may have perpendicular magnetic anisotropy (PMA).

In various embodiments the memory cell 300 may be or may be referred to as a magnetic tunnel junction (MTJ) for spin transfer torque magnetoresistive random access memory (STT-MRAM) cell or a spin transfer torque memory cell.

In various embodiments, a memory device may be provided. The memory device may further include a memory cell as described herein, and one or more electrodes coupled to the memory cell.

The memory device includes a memory cell including a magnetic pinned layer with a substantially fixed magnetization direction. The memory cell also includes a crystalline spacer layer in contact with the magnetic pinned layer. The memory cell further includes a magnetic storage layer including an amorphous interface sub-layer in contact with the crystalline spacer layer, the amorphous interface sub-layer including a first alloy of iron (Fe) and at least one element selected from a group consisting of boron (B), silicon (Si), aluminum (Al), and magnesium (Mg). The magnetic storage layer may additionally include an amorphous enhancement sub-layer in contact with the amorphous interface sub-layer, the amorphous enhancement layer including a second alloy of iron (Fe) and at least one element selected from a group consisting of boron (B), silicon (Si), aluminum (Al), and magnesium (Mg). The memory cell may also include a cap layer in contact with the amorphous enhancement sub-layer. The memory device may further include one or more electrodes coupled to the memory cell. A concentration of the at least one further element comprised in the first alloy and a concentration of the at least one further element comprised in the second alloy may be different.

The memory device may also include a transistor electrically coupled to the one or more electrodes. The transistor may be a complementary metal oxide semiconductor (CMOS) transistor. The transistor may be a n-channel metal oxide semiconductor (nMOS) transistor or a p-channel metal oxide semiconductor (pMOS) transistor. The transistor may be configured to control the operation of the memory cell, i.e. control the reading and writing of the memory cell.

In various embodiments, a memory device may be provided. The memory device may further include a plurality of memory cells as described herein. The memory device may include one or more electrodes coupled to the plurality of memory cells. The one or more electrodes may be coupled to at least two of the plurality of memory cells so that the at least two of the plurality of memory cells represent a single bit of data. In various embodiments, one of the one or more electrodes may be coupled to at least two of the plurality of memory cells, while other electrodes of the one or more electrodes may be coupled to one of the plurality of memory cells.

The memory device may also include at least one transistor electrically coupled to the one or more electrodes to control switching of current flow through the plurality of memory cells.

The memory device may be integrated into any one of a mobile phone, a set top box, a music player, a video player, an entertainment unit, a navigation device, a computer, a hand-held personal communication systems (PCS) unit, a portable data unit, and a fixed location data unit.

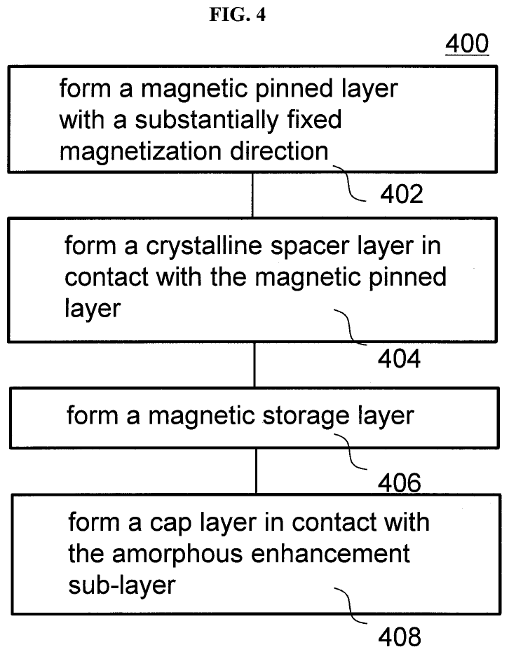

FIG. 4 is a schematic 400 showing a method of forming a memory cell according to various embodiments. The method includes, in 402, forming a magnetic pinned layer with a substantially fixed magnetization direction. The method also includes, in 404, forming a crystalline spacer layer in contact with the magnetic pinned layer. The method additionally includes, in 406, forming a magnetic storage layer. The magnetic storage layer may include an amorphous interface sub-layer in contact with the crystalline spacer layer, the amorphous interface sub-layer including a first alloy of iron (Fe) and at least one element selected from a group consisting of boron (B), silicon (Si), aluminum (Al), and magnesium (Mg). The magnetic storage layer may also include an amorphous enhancement sub-layer in contact with the amorphous interface sub-layer, the amorphous enhancement layer including a second alloy of iron (Fe) and at least one element selected from a group consisting of boron (B), silicon (Si), aluminum (Al), and magnesium (Mg). The method may also include, in 408, forming a cap layer in contact with the amorphous enhancement sub-layer. A concentration of the at least one further element comprised in the first alloy and a concentration of the at least one further element comprised in the second alloy may be different.

In other words, the method includes forming a magnetic pinned layer, magnetic storage layer, and a spacer layer between the magnetic pinned layer and the magnetic storage layer. The magnetic storage layer includes an amorphous interface sub-layer and an amorphous enhancement sub-layer in contact with the amorphous interface sub-layer. The memory cell also includes a cap layer in contact with the amorphous enhancement sub-layer. Both the amorphous interface sub-layer and the amorphous enhancement sub-layer include an alloy of iron and at least one element chosen from boron, silicon, aluminum and magnesium. However, the at least one element in the alloy of amorphous enhancement sub-layer may occupy a percentage different compared to the at least one element in the alloy of amorphous interface sub-layer.

The amorphous interface layer and the amorphous enhancement layer are formed from materials selected to remain amorphous after thermal annealing. The first alloy and the second alloy remain amorphous after thermal annealing. The method may include carrying out thermal annealing at a temperature selected from a range between about 350° C. and about 450° C. after forming the magnetic pinned layer, the crystalline pinned layer, and the cap layer.

A method of forming a memory device may also be provided. The method may include forming a memory cell as described herein. The method may also include forming one or more electrodes coupled to the memory cell.

The method includes forming a memory cell including forming a magnetic pinned layer with a substantially fixed magnetization direction. The method also includes forming a crystalline spacer layer in contact with the magnetic pinned layer. The method further includes forming a magnetic storage layer. The magnetic storage layer may include an amorphous interface sub-layer in contact with the crystalline spacer layer, the amorphous interface sub-layer including a first alloy of iron (Fe) and at least one element selected from a group consisting of boron (B), silicon (Si), aluminum (Al), and magnesium (Mg). The magnetic storage layer may also include an amorphous enhancement sub-layer in contact with the amorphous interface sub-layer, the amorphous enhancement layer including a second alloy of iron (Fe) and at least one element selected from a group consisting of boron (B), silicon (Si), aluminum (Al), and magnesium (Mg). The method may also include forming a cap layer in contact with the amorphous enhancement sub-layer. The method may additionally include forming one or more electrodes coupled to the memory cell. A concentration of the at least one further element comprised in the first alloy and a concentration of the at least one further element comprised in the second alloy may be different.

The method may include forming a transistor coupled to the memory cell via the one or more electrodes.

The method may also include using a back-end-of-line (BEOL) process after forming the magnetic tunneling junction including the magnetic pinned layer, the crystalline spacer layer and the magnetic storage layer.

The method may also include thermally annealing the memory device for stabilizing the transistor. The amorphous interface sub-layer and the amorphous enhancement sub-layer is configured to remain amorphous after the thermal annealing. The thermal annealing may be carried out at any temperature between about 350° C. and about 420° C., e.g. about 400° C., so that crystallization of the magnetic storage layer does not occur during BEOL process. In various embodiments, the method may include carrying out thermal annealing at a temperature selected from a range between 350° C. and about 420° C.

Various embodiments may also provide a memory cell formed by any method described herein. The method includes forming a memory cell including forming a magnetic pinned layer with a substantially fixed magnetization direction. The method also includes forming a crystalline spacer layer in contact with the magnetic pinned layer. The method further includes forming a magnetic storage layer. The magnetic storage layer may include an amorphous interface sub-layer in contact with the crystalline spacer layer, the amorphous interface sub-layer including a first alloy of iron (Fe) and at least one element selected from a group consisting of boron (B), silicon (Si), aluminum (Al), and magnesium (Mg). The magnetic storage layer may also include an amorphous enhancement sub-layer in contact with the amorphous interface sub-layer, the amorphous enhancement layer including a second alloy of iron (Fe) and at least one element selected from a group consisting of boron (B), silicon (Si), aluminum (Al), and magnesium (Mg). The method may also include forming a cap layer in contact with the amorphous enhancement sub-layer. A concentration of the at least one further element comprised in the first alloy and a concentration of the at least one further element comprised in the second alloy may be different.Various embodiments may also provide a memory device formed by any method described herein. The method may include forming a memory cell including forming a magnetic pinned layer with a substantially fixed magnetization direction. The method may also include forming a crystalline spacer layer in contact with the magnetic pinned layer. The method may further include forming a magnetic storage layer. The magnetic storage layer may include an amorphous interface sub-layer in contact with the crystalline spacer layer, the amorphous interface sub-layer including a first alloy of iron (Fe) and at least one element selected from a group consisting of boron (B), silicon (Si), aluminum (Al), and magnesium (Mg). The magnetic storage layer may also include an amorphous enhancement sub-layer in contact with the amorphous interface sub-layer, the amorphous enhancement layer including a second alloy of iron (Fe) and at least one element selected from a group consisting of boron (B), silicon (Si), aluminum (Al), and magnesium (Mg). The method may also include forming a cap layer in contact with the amorphous enhancement sub-layer. The method may additionally include forming one or more electrodes coupled to the memory cell. A concentration of the at least one further element comprised in the first alloy and a concentration of the at least one further element comprised in the second alloy may be different.

Various embodiments may provide a memory cell. The memory cell may include a magnetic pinned layer with a substantially fixed magnetization direction. The memory cell may also include a crystalline spacer layer in contact with or on the magnetic pinned layer. The memory cell may further include a magnetic storage layer in contact with or on the crystalline spacer layer. The memory cell may also include a cap layer in contact with or on the magnetic storage layer including at least one element selected from a group consisting of molybdenum (Mo) and tungsten (W). The magnetic storage layer may be amorphous.

In various embodiments, the magnetization of the magnetic pinned layer and the magnetization of the magnetic storage layer may be perpendicular to the film plane or an interface plane between the magnetic pinned layer and the crystalline spacer layer.

In various embodiments, the magnetic storage layer may include iron (Fe) and at least one element selected from a group consisting of boron (B), silicon (Si), aluminum (Al), and magnesium (Mg).

The magnetic storage layer may include an amorphous interface sub-layer in contact with or on the crystalline spacer layer, the amorphous interface sub-layer including a first alloy of iron (Fe), and at least one element selected from a group consisting of boron (B), silicon (Si), aluminum (Al), and magnesium (Mg). The magnetic storage layer may also include an amorphous enhancement sub-layer in contact with or on the amorphous interface sub-layer.

In various embodiments, a concentration of the at least one further element comprised in the first alloy and a concentration of the at least one further element comprised in the second alloy may be different. In various embodiments, a concentration of the at least one further element comprised in the second alloy may be higher than a concentration of the at least one further element comprised in the first alloy.

The amorphous interface sub-layer may include FeₐB_{b}Si_{c}Al_{d}Mgₑ. The amorphous enhancement sub-layer may include Fe_{A}B_{B}Si_{C}Al_{D}Mg_{E}. The values of a, b, c, d, e and A, B, C, D, E may be in atomic percentage (%).

A sum of b, c, d and e and be smaller than a sum of B, C, D and E.

In various embodiments, the value of “a” may be any value between 40 (%) and 90 (%).

The sum of b, c, d and e (i.e. b+c+d+e) may be any value between about 10 (%) to about 60 (%). The sum of a, b, c, d and e (i.e. a+b+c+d+e) may be 100 (%). For instance, the amorphous interface sub-layer may include Fe₉₀B₁₀, Fe₄₀B₂₀Si₂₀Al₂₀, or Fe₆₀B₁₀Si₁₀Al₁₀Mg₁₀.

In various embodiments, the value of A may be any value between about 40 (%) to about 90 (%). The sum of B, C, D and E (i.e. B+C+D+E) may be any value between about 10 (%) to about 60 (%). The sum of A, B, C, D and E (i.e. A+B+C+D+E) may be 100 (%).

The spacer layer may include magnesium oxide (MgO).

Various embodiments may provide a memory device. The memory device may include a magnetic pinned layer with a substantially fixed magnetization direction. The memory cell may also include a crystalline spacer layer in contact with the magnetic pinned layer. The memory cell may further include a magnetic storage layer in contact with the crystalline spacer layer. The memory cell may also include a cap layer in contact with the magnetic storage layer including at least one element selected from a group consisting of molybdenum (Mo) and tungsten (W). The magnetic storage layer may be amorphous. The memory device may further include one or more electrodes coupled to the memory cell.

Various embodiments may provide a method of forming a memory cell. The method may include forming a magnetic pinned layer with a substantially fixed magnetization direction. The method may also include forming a crystalline spacer layer in contact with the magnetic pinned layer. The method may additionally include forming a magnetic storage layer in contact with the crystalline spacer layer. The method may also include forming a cap layer in contact with the magnetic storage layer including at least one element selected from a group consisting of molybdenum (Mo) and tungsten (W). The magnetic storage layer may be amorphous.

The method may further include carrying out thermal annealing is at a temperature selected from a range of between 350° C. and 450° C. after forming the magnetic pinned layer, the spacer layer, the magnetic storage layer, and the cap layer.

Various embodiments may provide a method of forming a memory device. The method may include forming a memory cell including forming a magnetic pinned layer with a substantially fixed magnetization direction. The method may also include forming a crystalline spacer layer in contact with the magnetic pinned layer. The method may further include forming a magnetic storage layer in contact with the crystalline spacer layer. The method may also include forming a cap layer in contact with the magnetic storage layer including at least one element selected from a group consisting of molybdenum (Mo) and tungsten (W). The magnetic storage layer may be amorphous. The method may also include forming one or more electrodes coupled to the memory cell.

The method may further include using a thermal back-end-of-line (BEOL) process after forming a magnetic tunneling junction comprising of the magnetic pinned layer, the spacer layer and the magnetic storage layer. The magnetic storage layer may be configured to remain amorphous after the BEOL process.

Various embodiments may also provide a memory cell formed by any method described herein. The method may include forming a magnetic pinned layer with a substantially fixed magnetization direction. The method may also include forming a crystalline spacer layer in contact with the magnetic pinned layer. The method may additionally include forming a magnetic storage layer in contact with the crystalline spacer layer. The method may also include forming a cap layer in contact with the magnetic storage layer including at least one element selected from a group consisting of molybdenum (Mo) and tungsten (W). The magnetic storage layer may be amorphous.

Various embodiments may also provide a memory device formed by any method described herein. The method may include forming a memory cell. The method may include forming a magnetic pinned layer with a substantially fixed magnetization direction. The method may include forming a crystalline spacer layer in contact with the magnetic pinned layer. The method may include forming a magnetic storage layer in contact with the crystalline spacer layer. The method may include forming a cap layer in contact with the magnetic storage layer including at least one element selected from a group consisting of molybdenum (Mo) and tungsten (W). The magnetic storage layer may be amorphous. The method may additionally include forming one or more electrodes coupled to the memory cell.

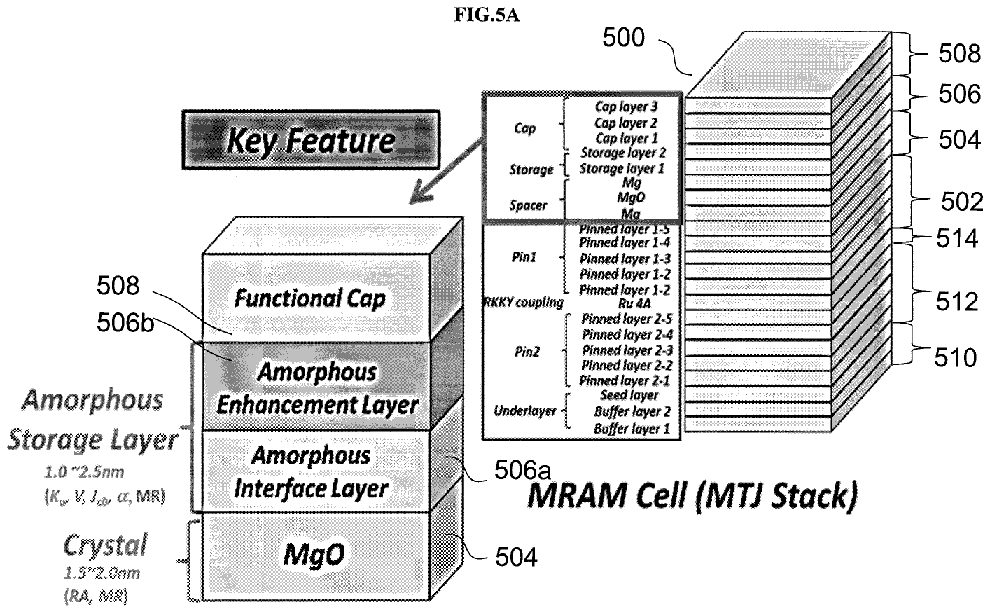

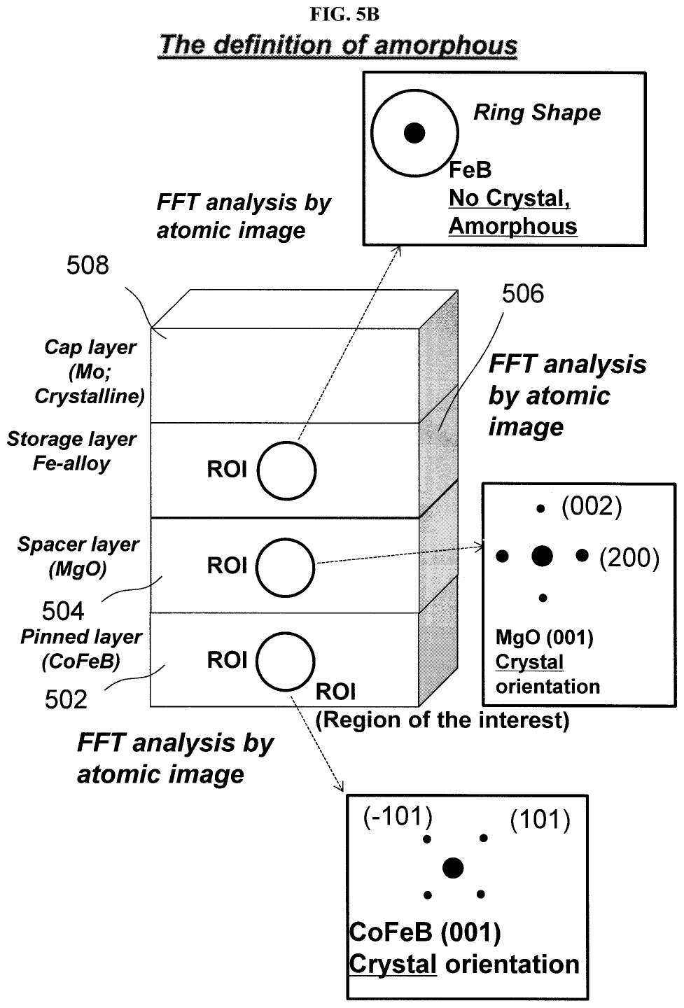

FIG. 5A shows a memory cell 500 according to various embodiments. The memory cell 500 may include a spacer layer 504 of magnesium oxide (MgO), an amorphous interface layer 506a on the spacer layer 504, an amorphous enhancement layer 506b on the amorphous interface layer 506a, and a cap layer 508 on the amorphous enhancement layer 506b.

The amorphous enhancement layer 506b and the amorphous interface layer 506a form the amorphous storage layer 506. The amorphous storage layer 506 includes or consists of the amorphous enhancement layer 506b and the amorphous interface layer 506a. The amorphous enhancement layer 506b and the amorphous interface layer 506a may help to stabilize the amorphous storage layer 506. The amorphous interface layer 506a may include Fe, and at least one element selected from a group consisting of B, Si, Al, and Mg. The amorphous enhancement layer 506b may include Fe, and at least one element selected from a group consisting of B, Si, Al, and Mg. The region interfacing with the spacer layer 504 may include FeB, FeSi, or FeAl.

The total amount of B, Si, Al and/or Mg may affect the stability of the amorphous storage layer 506. In order to improve stability, the total amount of B, Si, Al and/or Mg in the amorphous enhancement layer 506b may be higher than the total amount of B, Si, Al and/or Mg in the amorphous interface layer 506a.

The notion of the entire storage layer 506 being amorphous may go against “common sense”, i.e. the commonly held view that crystallization of the storage layer 506 is necessary.

The amorphous enhancement layer 506b and the amorphous interface layer 506a remain amorphous even after annealing at about 400° C. Thermal process at high temperatures of about 400° C. may be required in BEOL process. The use of stable material(s) in the amorphous enhancement layer 506b and the amorphous interface layer 506a may improve the stability, resulting in a low Gilbert damping factor α. An unstable, inhomogeneous structure may result in the increase of Gilbert damping factor α. As such, the use of the stable material(s) may help avoid this issue.

“Amorphous” used in the current context may following the usual meaning in material science. In other words, an amorphous material is a material that is lacking in long-range order characteristic of a crystal. A sample of the memory cell or magnetic tunneling junction may be observed by cross-sectional high-resolution transmission electron microscope (TEM).

FIG. 5B shows a schematic image for high-resolution transmission electron microscopy (TEM) being conducted at an interface between the amorphous interface layer and the amorphous enhancement layer of a part of the memory cell according to various embodiments shown in FIG. 5A. Cross-sectional high-resolution transmission electron microscope (TEM) is typically used. As the first step, a cross-sectional real image with high resolution may be obtained. After obtaining the real image, the periodic distance between neighbouring atoms in the region of interest (ROI) may be computationally calculated by Fast Fourier Transform (FFT) based on image recognition of the real image). This may be a useful method to clarify the crystalline structure (or amorphous structure) in a very narrow area in very thin multilayer. This method can be applied to determine or identify the crystalline structure in the spacer layer 504 (or amorphous structure in the storage layer 506). Results between neighbouring layers may be compared to obtain a clear conclusion.

The crystalline MgO spacer layer 504 may be easily identified from the neighbouring layers of metal alloys 502, 506 using TEM. Also, since the storage layer 506 is contacting crystalline MgO layer 504, the analysis of crystalline MgO layer 504 may be needed. When FFT analysis is adopted for the MgO layer 504, a spot pattern identifying the crystal structure may be obtained, as shown in FIG. 5B. Usually, MgO (001) crystal orientation can be identified.

Co₂₀Fe₆₀B₂₀ may be used for the pinned layer 502 in contact with the MgO layer 504. Although the as-deposited state of this layer is amorphous state, the annealing process after the deposition may result in crystalline Co₂₀Fe₆₀B₂₀ due to the driving force from MgO crystallization. As can be seen in FIG. 5B, crystalline CoFeB (001) can be detected by FFT analysis. CoFeB may have perpendicular magnetization direction to the film plane.

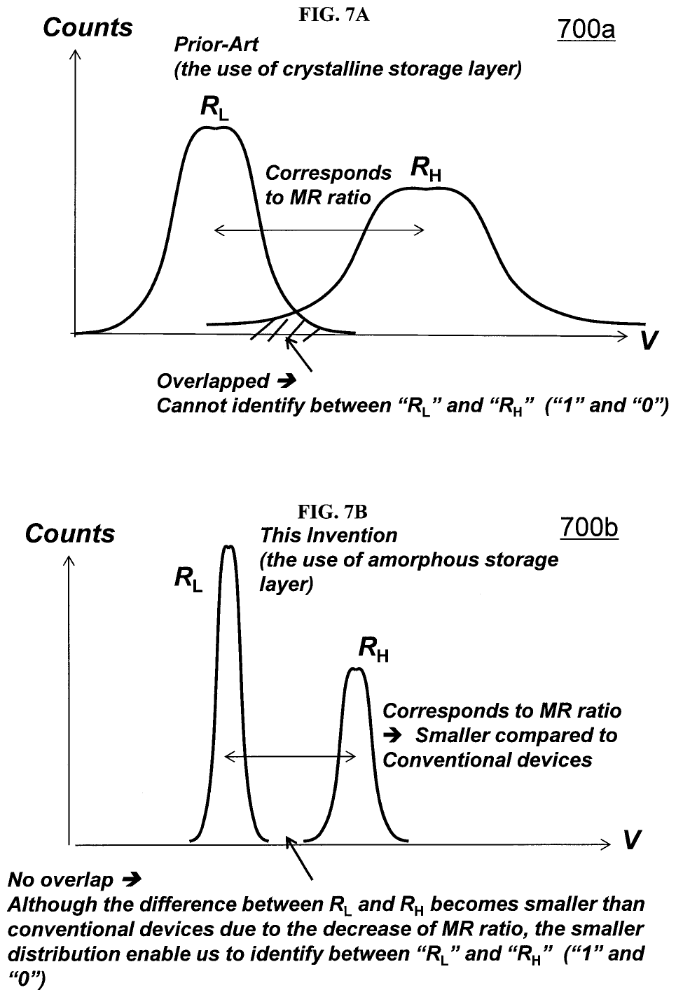

Conventional devices usually use CoFeB layer in perpendicular magnetization direction to the film plane in the storage layer. As such, conventional devices usually exhibit CoFeB (001) crystal structures in the storage layer, which is similar to the pinned layer. However, as already described, the use of a crystalline storage layer would make it very difficult to reduce switching current. Also, as will be shown in FIG. 7, the resistance distribution of the devices may be large.

Various embodiments may provide a magnetic storage layer include amorphous stable material. FIG. 5B shows a FeB based alloy being used as an example. When FFT analysis is carried out for the storage layer 508, the FFT data obtained is different from the MgO layer 504 and CoFeB layer 502. The spot pattern corresponding to crystalline structure cannot be detected for the case of the storage layer 502 in the device according to various embodiments. The FFT pattern instead shows a ring shape pattern, which is the evidence for amorphous structure.

By the above mentioned comparison with crystalline MgO spacer layer 504 (and crystalline pinned layer 502), the existence of amorphous storage layer may be detected or determined, thus allowing the identification of the amorphous nature of the storage layer 502.

Although an unstable inhomogeneous crystal structure in a storage layer results in the increase of Gilbert damping factor α, the use of amorphous stable material can avoid such an issue. Also, such inhomogeneous crystal structure causes a large distribution among devices. This will be more explained by using FIGS. 7A-B. The magnetization direction of the storage layer 506 may be switched between a first direction to indicate a first bit status (“0”) and a second direction opposite the first direction to indicate a second bit status (“1”). The magnetization direction of the storage layer may be dependent on the direction of the write current. During a write operation, if electrons flow from the pinned layer 502 to the storage layer 506, the magnetization direction of the storage layer 506 may be aligned in parallel to the magnetization direction of the pinned layer 502. Conversely, if electrons flow from the storage layer 506 to the pinned layer 502, the magnetization direction of the storage layer 506 may be aligned in an anti-parallel manner, i.e. in an opposite direction, to the magnetization direction of the pinned layer 502.

The resistance of the memory cell 500/MTJ may vary based on the magnetization direction of the storage layer 506. If the magnetization direction of the storage layer 506 and the magnetization direction of the pinned layer 502 are parallel to each other, the memory cell 500/MTJ may be in a low resistance state. Conversely, if the magnetization direction of the storage layer 506 and the magnetization direction of the pinned layer 502 are anti-parallel or opposite to each other, the memory cell 500/MTJ may be in a high resistance state.

The storage layer 506 is entirely amorphous with perpendicular magnetic anisotropy, even after the thermal anneal process at temperature of about 350° C. to about 420° C. The switching current may be reduced to ˜¼ of the switching current of a conventional storage layer via reducing the Gilbert damping factor α. Conventional storage layers typically use CoFeB. While as-deposited CoFeB may be in an amorphous state, the deposited CoFeB may be converted into a crystal structure after thermal annealing, which is a critical process during manufacture of STT-MRAM cells.

The storage layer 506 may include FeB (without Co), since FeB may exhibit good MR effect may has a more stable amorphous state compared to CoFeB. The cap layer 508 may be configured to help suppress crystallization of FeB. Alternatively, the storage layer 506 may include FeSi, which has an even more stable amorphous state compared to FeB, although the MR ratio of FeSi is smaller than FeB. Fe may be used as the main component of the amorphous storage layer 506 because the oxygen of the MgO in the spacer layer 504 and Fe of the amorphous storage layer 506 may realize perpendicular magnetic anisotropy (PMA), which may contribute to a low switching current. In general, the amorphous storage layer 506 may include an alloy including or consisting of Fe and at least one element selected from a group consisting of B, Si, Al, and Mg. Further, light elements such as B, Si, Al and/or Mg may be used to avoid spin-orbit scattering within the storage layer 506.

The amorphous interface layer 506a may cause the degradation of the MR effect, because the crystalline magnetic layer is needed to enhance MR ratio. However, the decrease of MR ratio may not necessarily means the difficulty of the identification between “1” and “0” increases, as schematically shown in FIGS. 7A-B. FIG. 7A is a plot 700a of the number of conventional memory cell devices as a function of voltage (in volts or V) showing the spread of devices at different resistance values when the devices are at the “0” state and at the “1” state. FIG. 7B is a plot 700b of the number of memory cell devices according to various embodiments as a function of voltage (in volts or V) showing the spread of devices at different resistance ratios values when the devices are at the “0” state and at the “1” state. Comparing FIG. 7A and FIG. 7B, the devices according to various embodiments may exhibit a smaller MR ratio compared to conventional devices. However, the devices according to various embodiments may also exhibit a narrower distribution of resistance values compared to conventional devices.

Although the use of amorphous storage layer decreases the MR ratio as drawback, the use of an amorphous storage layer has clear benefits in terms of a narrower distribution among devices. This benefit may become more distinct with decreasing the memory cell size.

As shown in FIG. 7A, for the case of using crystalline free layer, the distribution of resistance values is relatively large. This causes the distribution overlap between low resistance state and high resistance state among memory cell devices to be significant. Since “1” or “0” in the memory can be identified by comparing with reference resistance (or voltage=resistance×sense current), it may not be possible to identify the state of the devices within the overlapped region. The mean difference between low resistance state (low voltage state) and high resistance state (high voltage state) corresponds to the MR ratio.

As shown in FIG. 7B, for the case of using an amorphous storage layer, the distribution of resistance values is smaller. The narrower distribution among many devices due to use of amorphous storage layer can eliminate the overlap region, as shown in FIG. 7B. Note that the mean resistance difference between low resistance state (low voltage) and high resistance state (high voltage) becomes smaller than FIG. 7A due to the decrease of MR ratio. Comparing FIG. 7A and FIG. 7B, while a large MR ratio (large mean difference between low resistance state and high resistance state) may make determining or distinguishing between the two states easier, a narrower resistance ratio may help compensate for a smaller MR ratio, leading to improved readability.

The amorphous interface layer 506a and the amorphous enhancement layer 506b functions as a storage layer having one magnetization direction. The amorphous interface layer 506a and the amorphous enhancement layer 506b may be coupled to each other strongly enough so that the amorphous interface layer 506a and the amorphous enhancement layer 506b have the same magnetization direction.

A small saturation magnetization Bₛ of the storage layer 506 may be desirable, as a large Bₛ may result in an increase of the switching current. The at least one element selected from a group consisting of B, Si, Al, and Mg may be used to control the Bₛ of the storage layer 506. Further, the thickness of the storage layer 506 should not be too large in order to realize a small switching current. The thickness of the amorphous storage layer 506 may be any value from about 1 nm to about 2.5 nm. The amorphous storage layer 506 may be magnetic.

As also shown in FIG. 5A, the memory cell 500 may also include an underlayer 510, a pinning layer 512 on the underlayer 510, a RKKY coupling layer 514 on the pinning layer 512, and a pinned layer 502 on the RKKY coupling layer 514. The spacer layer 504 may be on the pinned layer 502. The underlayer 510 may include a buffer layer including one or more buffer sub-layers, and a seed layer over or on the buffer layer. The pinning layer 512 may include one or more sub-layers. The pinned layer 502 may also include one or more sub-layers. The pinned layer 502 may also be referred to as a reference layer.

The one or more buffer sub-layer may be formed on or over the lower electrode. The one or more buffer sub-layers may be required for the film growth of MTJ which may include a plurality of atomic thin layers. The one or more buffer layers may work as good adhesion layers between the lower electrode and the magnetic tunneling junction (MTJ), and may enable the thickness of the seed layer to be reduced. The one or more buffer layers may include, for example, Ta, Ti, V, W, Zr, Hf, Cr, or an alloy which contains one or more of such metals. Other suitable candidates may include TaN or TiN. The one or more buffer sub-layers may form a multi-layer structure. The thickness of the buffer layer may be between about 0.5 nm to about 3 nm, preferably between about 0.8 nm to about 1.5 nm, in order to avoid increasing the roughness of the MTJ. Weak plasma cleaning may be required to remove dirt particles from the lower electrode before forming the one or more buffer layers by deposition.

The seed layer may be formed on the buffer layer by deposition to enhance the crystal growth of the MTJ. The seed layer may have a crystal structure such as face-centered cubic (fcc), body-centered cubic (bcc), or hexagonal close-packed (hcp). The seed layer may also control the grain size of the MTJ. If the pinning layer 512 includes (Co/Ni)_{N} multilayer (where N represents the number of Co/Ni layers), or (Co/Pt)_{N} multilayer (where N represents the number of Co/Pt layers), a fcc or hcp crystal structure may be preferred as a seed layer. The seed layer may include NiCr, NiFeCr, NiFeHf, NiFeZr, Pt, Ru, Cu, Ir, or any alloy including one of more of these materials. The seed layer may instead include TaN or TiN. The seedlayer may be a multilayer structure, i.e. it may include a plurality of sub-layers. The total thickness of the seed layer may be any value between about 1 nm to about 3 nm, or between about 0.8 nm to about 1.5 nm to avoid increasing the roughness of the MTJ.

The pinning layer 512, the RKKY coupling layer 514 and the pinned layer 502 may form the synthetic antiferromagnetic pin (Sy-AF pin). The pinning layer 512 may include a ferromagnetic material and may exhibit a strong magnetic anisotropy. The pinning layer 512 may possess perpendicular magnetic anisotropy (PMA), which may reduce switching current, and/or reduce the footprint of the MTJ to realize larger capacity. For instance, a (Co/Ni)_{N} multilayer or a (Co/Pt)_{N} multilayer may be used as a perpendicular magnetic anisotropic pinning layer. Each layer of Co, Ni, or Pt may be a few angstroms thick. The thickness of the pinning layer 512 may be dependent on N. The thickness of the pinning layer 512 may be about 2 nm to about 4 nm thick. The value of N of the pinning layer 512 may vary from 2 to 4. As long as the pinning field is strong enough, a thinner thickness may be preferred to reduce the roughness of the MTJ. The pinning layer 512 may alternatively include an ordered alloy such as FePt or CoPt.

The pinning performance may be strongly dependent on the seed layer. A good crystal structure may result in a stronger and better pinning performance. While a thicker seed layer may result in a better crystal structure, the thicker seed layer may also result in an increase in the roughness of the interface, which may result in the decrease in pinning performance and decrease in MR. The MR and PMA of the storage layer may be also decreased. Due to such constraints, the use of a thick seed layer may not be preferred. The seed layer may typically be about or less than 3 nm. In order to achieve good crystal structure for a thinner seed layer, the use of the buffer layers may be required. Further, since the seed layer and the pinning layer may affect the crystal structure of the spin-dependent scattering unit, the seed layer and the pinning layer may also affect MR.

The RKKY coupling layer 514 may make strong anti-ferromagnetic coupling between the pinning layer 512 and the pinned layer 502. The RKKY coupling layer 514 may include Ru. The coupling layer 514 may be about 0.4 nm thick for the first peak of RKKY coupling, or may be about 0.8 nm thick for the second peak of RKKY coupling. The pinning strength may be enhanced due to the RKKY coupling. The synthetic antiferromagnetic pin (Sy-AF pin) may serve to reduce stray field from the pinned layer 502 to the storage layer 506. Decreasing the size of the MRAM cell (i.e. increasing the density of the MRAM) may cause the stray field to increase for the same pinning layer 512 structure. Accordingly, the Sy-AF pin may become even more critical.

The pinned layer 502 may include ferromagnetic material. The pinned layer 502 may also include non-magnetic materials to enhance the performance. The magnetization direction of the pinned layer 502 may remain the same, irrespective of whether the bit state of the memory cell 500 is in a first state (“0”) or a second state (“1”). The fixed magnetization direction of the pinned layer 502 may be due to the effect of the pinning layer 512 through the RKKY coupling layer 514. Even though the pinned layer 502 may not have enough magnetic anisotropy, the pinning strength of the pinned layer 502 may be sustained based on the pinning layer 512 through the RKKY coupling layer 514. The pinned layer 502 may be a component of the spin-dependent scattering unit which provides magnetoresistive (MR) effect. The pinned layer 502 may provide a greater effect compared to the pinning layer 512. As the resistance is dependent on the relative angle between the magnetization direction of the storage layer 506 and the pinned layer 502, the pinned layer 502 may work as a reference to detect the bit status.

A (Co/Ni)_{N} multilayer or (Co/Pt)_{N} multilayer may be used as part of the pinned layer 502 to realize perpendicular magnetic anisotropy (PMA). In other words, sub-layers of cobalt (Co) and either nickel (Ni) or platinum (Pt) may form at least a part of the pinned layer 502. However, as the (Co/Ni)_{N} multilayer or (Co/Pt)_{N} multilayer may not show sufficient MR effect, a CoFeB sub-layer may also be formed by deposition on or over the (Co/Ni)_{N} multilayer or (Co/Pt)_{N} multilayer. Also, since the Bₛ.t (product of magnetization and thickness) of the pinning layer 512 and the pinned layer 502 may be roughly required to be balanced, the number of sub-layers N of the multilayer of the pinned layer 502 may be smaller than that for the pinning layer 512 because of the CoFeB sub-layer comprised in the pinned layer 502. N may be any value from 1 to 3. The thickness of the CoFeB sub-layer may be any value from about 1 nm to about 1.5 nm, while the thickness of the multilayer under the CoFeB sub-layer may be any value from about 1 nm to about 3 nm.

The pinning layer 512 may include one or more non-magnetic materials. The pinned layer 502 may include a thin tantalum (Ta) insertion sub-layer for promoting crystallization of the adjacent CoFeB sub-layer. The Ta insertion sub-layer may be below the CoFeB sub-layer. The as-deposited CoFeB sub-layer is amorphous, but change to a crystal structure after a thermal annealing process. The use of crystallized CoFeB may be considered to be important to obtaining a magnetoresistive effect. The tantalum (Ta) insertion sub-layer may absorb B from the CoFeB sub-layer during the annealing process, which may help in crystallization of the CoFeB sub-layer. The pinned layer 502 may be thin enough to have a single fixed magnetization, even if a non-magnetic material is included in the pinned layer 502. The non-magnetic material comprised in the pinned layer 502 may form a layer of a thickness less than or equal to about 1 nm, preferably less than about 0.5 nm. At such thicknesses, the upper Ta sub-layer and the lower Ta sub-layer (separated by the non-magnetic material sub-layer) may be strongly ferromagnetically coupled.

The spacer layer 504 may work as a tunneling barrier. The spacer layer 504, with the pinned layer 502 and the storage layer 506 may form the spin-dependent scattering unit for causing the MR effect.

In various embodiments, the spacer layer 504 may include or consist of magnesium oxide. The spacer layer 504 may initially include a Mg metal sub-layer. The Mg metal may be oxidized to MgO by movement of oxygen from MgO sub-layers adjoining the Mg metal sub-layer.

The spacer layer 504 may need to be crystallized to realize the MR effect. The crystallization may be realized by thermal annealing after the layers for the MTJ are deposited. The annealing temperature may be any value from about 350° C. to about 420° C. The product of the resistance and area (RA) may be controlled, e.g. by varying the thickness. The RA may be any value from about 0.1 Ωμm² to about 20 Ωμm². The thickness of the MgO may be any value in a range from about 1 nm to about 2.5 nm. The MgO layer may be formed by surface oxidation process after the deposition of magnesium metal. The oxidation may be carried out by natural oxidation or plasma oxidation. Natural oxidation may be employed to realize a smaller RA, while weak plasma oxidation may be used to obtain a higher MR ratio.

The cap layer 508 may include one or more sub-layers. The cap layer 508 may also be referred to as a functional cap layer. The cap layer 508 may include MgO to realize large retention, as the oxygen of MgO may interact with the storage layer 506 to induce PMA, and also reduce switching current. Alternatively, the cap layer 508 may include Mo, W or any alloy including Mo and/or W. The use of the amorphous enhancement layer 506b and the cap layer 508 with Mo, W, or any alloy including Mo and/or W may satisfy both thermal stability and lower switching current, due to a more stable amorphous storage layer 506. The stability of the amorphous state of the storage layer 506 may also be dependent on the diffusion control of the elements B, Si, Al and/or Mg in the storage layer 506.

The memory cell 500 may further include a protection layer (alternatively referred to as additional layer) on or over the cap layer 508 to protect the underlying layers from damage during lithography. The protection layer may include Ta, Ru, Cu, or the laminated stack including one or more of these elements.

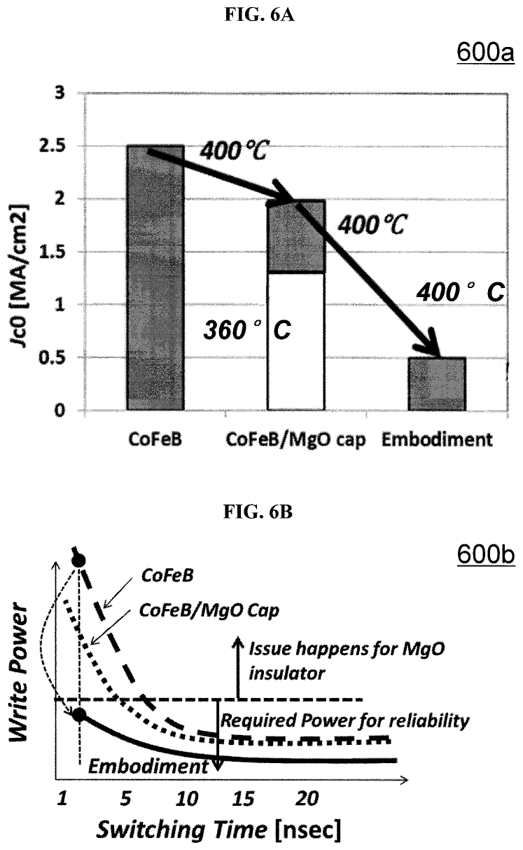

FIG. 6A is a schematic plot 600a of current density J_{c0} (mega-amperes per square centimeter or MA/cm²) comparing the storage layer according to various embodiments with conventional storage layers based on modeling. FIG. 6A shows a modeling result. An example of the structure has an amorphous storage layer with the structure Ta (1.2 nm)/Pt (2.0 nm)/(Co (0.3 nm)/Pt (0.5 nm)) ×6/Co (0.5 nm)/Ru (0.8 nm)/Co (0.5 nm)/(Co (0.3 nm)/Pt (0.5 nm) ×2//TaFe (0.4 nm)/Co₂₀Fe₆₀B₂₀ (0.8 nm)/MgO (1.2 nm)/Fe₈₀B₂₀ (1.2 nm)/Mo (2 nm)/Ta (3 nm)/Ru (2 nm)/Ta (3 nm). In this embodiment, the amorphous interface layer and the amorphous enhancement layer includes Fe₈₀B₂₀. Instead of Fe₈₀B₂₀ layer, the amorphous interface layer of Fe₉₀B₁₀ (0.7 nm), and the amorphous enhancement layer of Fe₇₀B₃₀ (0.5 nm) may also be used.

The cap layer includes Mo, and this layer may be important to realize high thermal tolerance against 400° C. Mo has a crystal structure. As such, the amorphous storage layer (FeB) is sandwiched by a crystalline MgO spacer layer and a crystalline Mo cap layer. Since the storage layer is easy to be crystallized by such a structure, the use of conventional CoFeB results in crystallization, which may not lead to a reduction in switching current. Also, the distribution of the resistance of devices employing a crystalline free layer may not be narrow. Accordingly, it may be important that the magnetic storage layer has an amorphous structure. On the top of Mo cap layer, a Ta/Ru/Ta layer is used as protection layer. The spacer layer includes MgO, while the pinned layer is Co (0.5 nm)/(Co (0.3 nm)/Pt (0.5 nm)×2/TaFe (0.4 nm)/Co₂₀Fe₆₀B₂₀ (0.8 nm). The RKKY coupling layer includes Ru, the seed layer includes Pt, and the buffer layer includes Ta.

The annealing temperature is about 30 minutes at about 400 degree. Celsius. The conventional storage layers Co₂₀Fe₆₀B₂₀ (1.2 nm)/Ru (2 nm) (named as “CoFeB”) and Co₂₀Fe₆₀B₂₀ (1.2 nm)/MgO (1 nm) (named as “CoFeB/MgO cap”) are also compared.

By using a whole or entire amorphous storage layer, the J_{c0} may be decreased by ¼ compared to conventional CoFeB, due to the decrease of the damping factor α. The BEOL process may require an annealing temperature of 400° C. For such a high temperature, annealing for a duration more than 10 minutes may cause a conventional storage layer which contains poly-crystals to exhibit increased J_{c0}due to the unstable amorphous structure. Consequently, a conventional storage layer may not be able to realize a small J_{c0}. A BEOL process may refer to the processes required after MTJ deposition/STT-MRAM formation, in which CMOS transistor devices are fabricated on the same substrate (as the STT-MRAM MTJ).

In contrast, various embodiments may reduce the J_{c0} due to the stable homogenous amorphous storage layer. Various embodiments may not cause undesired scattering due to a non-homogenous crystal structure, which may result in a high Gilbert damping factor α.

Various embodiments may exhibit a decrease in J_{c0}. Consequently, various embodiments may exhibit a faster switching speed. FIG. 6B is a plot 600b of critical current density J_{c0} as a function of switching time (nanoseconds or nsec) showing the decreased critical current density J_{c0} exhibited by the storage layer according to various embodiments.

The effect of the small α may be significant for a faster switching speed, because the fast switching may be achieved by precession mode, not by thermal mode. The decrease of a may be related to the faster switching speed.

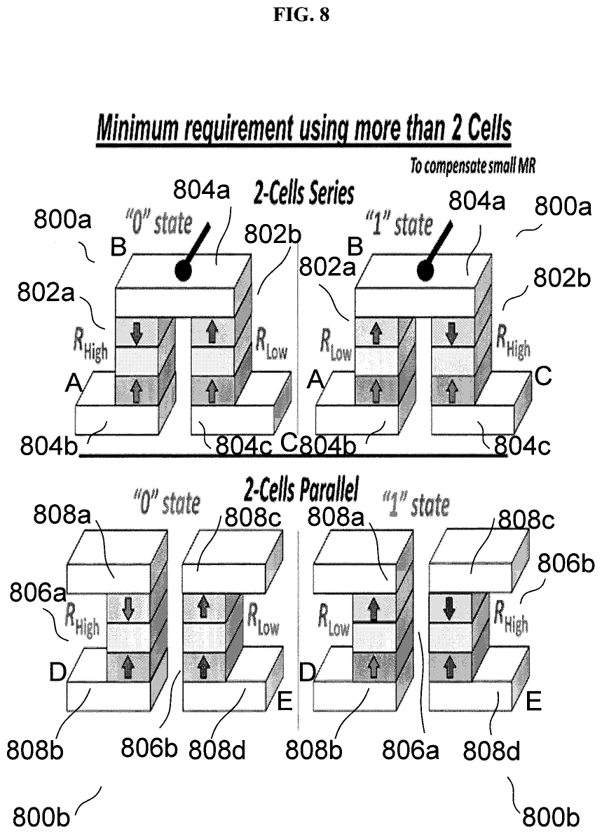

In various embodiments, the MR ratio may be decreased. However, the decreased MR ratio may not become a bottleneck in most practical use. This is because that the use of amorphous storage layer enables us to realize smaller distribution than conventional crystalline storage layer, as highlighted earlier. Also, multiple MTJs may be used for one bit cell as will be explained in FIG. 8. Various embodiments may be suitable for cache applications for which the weak non-volatility, smaller MR ratio and small J_{c0} may be acceptable.

Some examples of a memory cell (in the order of spacer layer/amorphous storage layer/cap layer) may include MgO (1.2 nm)/Fe₈₀B₂₀ (0.7 nm)/Fe₈₀Si₂₀ (0.5 nm)/Mo (2.0 nm), MgO (1.2 nm)/Fe₈₀B₂₀ (1.2 nm)/W (2.0 nm), MgO (1.2 nm)/Fe₈₀B₂₀ (1.2 nm)/MgO (1 nm), MgO (1.2 nm)/Fe₇₀Si₃₀ (1.5 nm)/Mo (2.0 nm), MgO (1.2 nm)/Fe₇₀Si₃₀ (1.5 nm)/W (2.0 nm), or MgO (1.2 nm)/Fe₇₀Si₃₀ (1.5 nm)/MgO (1 nm).

Among the several candidates of capping layer, the use of Mo or W may be preferred. Further, the use of Mo alloy may be preferred. Crystalline Mo may be deposited on the amorphous storage layer. One reason for using Mo in the cap layer for amorphous storage layer is to ensure a good thermal tolerance during the BEOL process, which may be around 400 degrees Celsius. In various embodiments, the memory cell may include crystalline MgO spacer layer/amorphous Fe-based storage layer (such as FeB-alloy)/crystalline Mo cap layer.

The selection of the material comprised in the cap layer may affect the amorphous stability of the storage layer. This is because elements such as boron (B) in the storage layer may play an important role to maintain as amorphous structure. The diffusion of the elements (e.g. B) may be affected by the cap layer material. Using a material such as Mo in the cap layer instead of MgO may help better control diffusion of elements such as B in the storage layer.

In order to illustrate the importance of the choice of material in the cap layer to maintain the amorphous stability of the storage layer, tantalum (Ta) may be used to form the cap layer. In such a case, even if the storage layer has the same composition as in the Mo cap layer example, it is difficult to maintain amorphous structure of the storage layer during heating (either annealing process or BEOL process). This is because elements such as B in the storage layer may easily diffuse to the Ta cap layer, and the reduction of elements such as B in the storage layer may result in the crystallization of the storage layer. Accordingly, the cap layer material selection, in addition to the composition of the magnetic storage layer, may be critically important to realize the amorphous nature of the magnetic storage layer. Mo may be used in conjunction with a relatively wide range of compositions of the storage layer.

Other examples of a memory cell may include (in the order of spacer layer/amorphous interface layer/amorphous enhancement layer/cap layer) may include MgO (1.2 nm)/Fe₈₀B₂₀ (0.7 nm)/Fe₇₀B₂₀Mg₁₀ (0.7 nm)/Mo (1.5 nm), MgO (1.2 nm)/Fe₈₀B₂₀ (0.7 nm)/Fe₇₀B₂₀Mg₁₀ (0.7 nm)/W (1.5 nm), or MgO (1.2 nm)/Fe₈₀B₂₀ (0.7 nm)/Fe₇₀B₂₀Mg₁₀ (0.7 nm)/MgO (1 nm). The total composition of the elements (i.e. B and Mg) in the amorphous enhancement layer may be higher than the composition of elements (i.e. B) in the amorphous interface layer.

Additional examples of a memory cell may include (in the order of spacer layer/amorphous interface layer/amorphous enhancement layer/cap layer) may include MgO (1.2 nm)/Fe₈₀Si₂₀ (0.7 nm)/Fe₇₀Si₂₀Mg₁₀ (0.7 nm)/Mo (1.5 nm), MgO (1.2 nm)/Fe₈₀Si₂₀ (0.7 nm)/Fe₇₀Si₂₀Mg₁₀ (0.7 nm)/W (1.5 nm), or MgO (1.2 nm)/Fe₈₀Si₂₀ (0.7 nm)/Fe₇₀Si₂₀Mg₁₀ (0.7 nm)/MgO (1 nm). The total composition of the elements (i.e. Si and Mg) in the amorphous enhancement layer may be higher than the composition of elements (i.e. Si) in the amorphous interface layer.

Further examples of a memory cell may include (in the order of spacer layer/amorphous interface layer/amorphous enhancement layer/cap layer) may include MgO (1.2 nm)/Co₃₀Fe₄₀B₃₀ (0.7 nm)/Co₂₅Fe₃₅B₄₀ (0.7 nm)/Mo (1.5 nm), MgO (1.2 nm)/Co₃₀Fe₄₀B₃₀ (0.7 nm)/Co₂₅Fe₃₅B₄₀ (0.7 nm)/W (1.5 nm), MgO (1.2 nm)/Co₃₀Fe₄₀B₃₀ (0.7 nm)/Co₂₅Fe₃₅B₄₀ (0.7 nm)/MgO (1.5 nm). The total composition of the elements (i.e. B) in the amorphous enhancement layer may be higher than the composition of elements (i.e. B) in the amorphous interface layer.

Yet further examples of a memory cell may include (in the order of spacer layer/amorphous interface layer/amorphous enhancement layer/cap layer) may include MgO (1.2 nm)/Co₂₀Fe₆₀B₂₀ (0.7 nm)/Fe₇₀B₃₀ (0.7 nm)/Mo (1.5 nm), MgO (1.2 nm)/Co₂₀Fe₆₀B₂₀ (0.7 nm)/Fe₇₀B₃₀ (0.7 nm)/W (1.5 nm), or MgO (1.2 nm)/Co₂₀Fe₆₀B₂₀ (0.7 nm)/Fe₇₀B₃₀ (0.7 nm)/MgO (1.5 nm) The total composition of the elements (i.e. B) in the amorphous enhancement layer may be higher than the composition of elements (i.e. B) in the amorphous interface layer. Also, the amorphous enhancement layer has a smaller concentration of Co compared to the amorphous interface layer. FeB may have an amorphous state that is more stable, and may be used in the amorphous enhancement layer 506b.

The composition of the amorphous interface sub-layer may be expressed as FeₐB_{b}Si_{c}Al_{d}Mgₑ, and the composition of the amorphous enhancement sub-layer may be expressed as Fe_{A}B_{B}Si_{C}Al_{D}Mg_{E}. For such expression, a sum of b, c, d and e may be smaller than a sum of B, C, D and E. Also, a may be any value between 40 and 90; a sum of b, c, d and e may be any value between 10 and 60; and a sum of a, b, c, d and e maybe 100.

Since the existing cache memory (SRAM) needs a large footprint (6 transistors), there may be space margin for MRAM to compete with SRAM. Cache MRAM may use more than 2 MTJ stacks for 1 bit, which means small MR ratio can be compensated by the use of multiple MTJs. Various embodiments may have a slightly decreased magnetoresistance (MR) ratio. Various embodiments may still be suitable for cache applications as cache application may not require a high MR ratio.

Each memory device may include two memory cells for representing 1 data bit in order to compensate for the small magnetoresistance (MR) as a result of the amorphous storage layer (which may be alternatively referred to as free layer). FIG. 8 shows memory devices 800a, 800b according to various embodiments. The memory devices 800a and 800b in FIG. 8 are not drawn to scale. The size and/or aspect ratio of the memory devices 800a, 800b may differ from that shown in FIG. 8. The memory device 800a may include a first memory cell 802a and a second memory cell 802b. The first memory cell 802a and the second memory cell 802b may be coupled in series. As shown in FIG. 8, a first end of the first memory cell 802a and a first end of the second memory cell 802b may be in contact with the first electrode 804. A second electrode 804b may be in contact with a second end of the first memory cell 802a, and a third electrode 804c may be in contact with a second end of the second memory cell 802b. In a first logic state (“0” state), the magnetization direction of the storage layer and the magnetization direction of the pinned layer of the first memory cell 802a may be in opposing directions to cause a high resistance (R_{High}), and the magnetization direction of the storage layer and the magnetization direction of the pinned layer of the second memory cell 802b may be in the same direction to cause a low resistance (R_{Low}). In a second logic state (“1” state), the magnetization direction of the storage layer and the magnetization direction of the pinned layer of the first memory cell 802a may be in the same direction to cause a low resistance (R_{Low}), and the magnetization direction of the storage layer and the magnetization direction of the pinned layer of the second memory cell 802b may be in opposing directions to cause a high resistance (R_{High}).

The memory device 800b may include a first memory cell 806a and a second memory cell 806b. The first memory cell 806a and the second memory cell 806b may be coupled in parallel. As shown in FIG. 8, a first end of the first memory cell 806a may be in contact with a first electrode 808a and a second end of the first memory cell 806a may be in contact with a second electrode 808b. A first end of the second memory cell 806b may be in contact with a third electrode 808c and a second end of the second memory cell 806b may be in contact with a fourth electrode 808d. In a first logic state (“0” state), the magnetization direction of the storage layer and the magnetization direction of the pinned layer of the first memory cell 806a may be in opposing directions to cause a high resistance (R_{High}), and the magnetization direction of the storage layer and the magnetization direction of the pinned layer of the second memory cell 806b may be in the same direction to cause a low resistance (R_{Low}). In a second logic state (“1” state), the magnetization direction of the storage layer and the magnetization direction of the pinned layer of the first memory cell 806a may be in the same direction to cause a low resistance (R_{Low}), and the magnetization direction of the storage layer and the magnetization direction of the pinned layer of the second memory cell 806b may be in opposing directions to cause a high resistance (R_{High}).

One or more transistors (not shown in FIG. 8) may be connected to the memory devices 800a, 800b. The transistor connection points may be A, B or C for memory device 800a, and D or E for memory device 800b.

The magnetization directions of the storage layer in memory devices 800a, 800b may be opposite to represent complementary logic states for better readability. For memory device 800a, the first end of the memory cell 802a and the second end of the memory cell 802b may be in contact with a common electrode 804a. During writing, a write current may be supplied to the memory device 800a. Electrons may flow from the pinned layer to the storage layer in memory cell 802a, and may flow from the storage layer to the pinned layer in memory cell 802b. It may also be envisioned that instead of the top end of the memory cell 802a and the top end of the memory cell 802b may be joined to a common electrode, the bottom end of the memory cell 802a and the bottom end of the memory cell 802b be joined to a common electrode in various other embodiments. In various embodiments, the transistor may be connected to A terminal or C terminal while the B terminal may be grounded during reading. In various other embodiments, a bias voltage may be supplied between terminal A and terminal B, which a transistor may be connected to B terminal for reading the bit state. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A memory cell comprising:
a magnetic pinned layer with a substantially fixed magnetization direction;
a crystalline spacer layer in contact with the magnetic pinned layer;
a magnetic storage layer comprising:
an amorphous interface sub-layer in contact with the crystalline spacer layer, the amorphous interface sub-layer comprising a first alloy of iron (Fe) and at least one element selected from a group consisting of boron (B), silicon (Si), aluminium (Al), and magnesium (Mg); and
an amorphous enhancement sub-layering contact with the amorphous interface sub-layer, the amorphous enhancement sub-layer comprising a second alloy of iron (Fe) and at least one element selected from a group consisting of boron (B), silicon (Si), aluminium (Al), and magnesium (Mg); and
a cap layer in contact with the amorphous enhancement sub-layer;
wherein a concentration of the at least one further element comprised in the first alloy and a concentration of the at least one further element comprised in the second alloy are different.

2. The memory cell according to claim 1,
wherein the at least one element of the first alloy and the at least one element of the second alloy are the same.

3. The memory cell according to claim 1,
wherein a concentration of the at least one element of the second alloy is higher than a concentration of the at least one element of the first alloy.

4. The memory cell according to claim 1,
wherein the amorphous interface sub-layer comprises FeₐB_{b}Si_{c}Al_{d}Mgₑ;
wherein the amorphous enhancement sub-layer comprises Fe_{A}B_{B}Si_{C}Al_{D}Mg_{E}; and
wherein a sum of b, c, d and e is smaller than a sum of B, C, D and E.

5. The memory cell according to claim 4,
wherein a is any value between 40 and 90;
wherein a sum of b, c, d and e is any value between 10 and 60; and
wherein a sum of a, b, c, d and e is 100.

6. The memory cell according to claim 1,
wherein the cap layer comprises at least one material selected from a group consisting of molybdenum (Mo), tungsten (W), and magnesium oxide (MgO).

7. The memory cell according to claim 1,
wherein the spacer layer comprises magnesium oxide (MgO).

8. A memory device comprising:
a memory cell comprising:
a magnetic pinned layer with a substantially fixed magnetization direction;
a crystalline spacer layer in contact with the magnetic pinned layer;
a magnetic storage layer comprising:
an amorphous interface sub-layer in contact with the crystalline spacer layer, the amorphous interface sub-layer comprising a first alloy of iron (Fe) and at least one element selected from a group consisting of boron (B), silicon (Si), aluminium (Al), and magnesium (Mg); and
an amorphous enhancement sub-layer in contact with the amorphous interface sub-layer, the amorphous enhancement sub-layer comprising a second alloy of iron (Fe) and at least one element selected from a group consisting of boron (B), silicon (Si), aluminium (Al), and magnesium (Mg); and
a cap layer in contact with the amorphous enhancement sub-layer; and
one or more electrodes coupled to the memory cell;
wherein a concentration of the at least one further element comprised in the first alloy and a concentration of the at least one further element comprised in the second alloy are different.

9. A method of forming a memory cell, the method comprising:
forming a magnetic pinned layer with a substantially fixed magnetization direction;
forming a spacer layer in contact with the magnetic pinned layer;
forming a magnetic storage layer, the magnetic storage layer comprising:
an amorphous interface sub-layer in contact with the crystalline spacer layer, the amorphous interface sub-layer comprising a first alloy of iron (Fe) and at least one element selected from a group consisting of boron (B), silicon (Si), aluminium (Al), and magnesium (Mg); and
an amorphous enhancement sub-layer in contact with the amorphous interface sub-layer, the amorphous enhancement layer comprising a second alloy of iron (Fe) and at least one element selected from a group consisting of boron (B), silicon (Si), aluminium (Al), and magnesium (Mg); and
forming a cap layer in contact with the amorphous enhancement sub-layer;
wherein a concentration of the at least one further element comprised in the first alloy and a concentration of the at least one further element comprised in the second alloy are different.

10. A method of forming a memory cell according to claim 9, further comprising:
carrying out thermal annealing is at a temperature selected from a range of between 350° C. and 420° C. after forming the magnetic pinned layer, the spacer layer, the magnetic storage layer, and the cap layer.
